(19) United States
(12) Patent Application Publication
(10) Pub. No.: US 2003/0010652 A1
(43) Pub. Date: Jan. 16, 2003

(54) Method of enhanced heat extraction from a geothermal heat source for the production of electricity thermoelectrically and mechanically via the high-pressure injection of a cryogen into a U-tube or open tube heat exchanger within a geothermal heat source, such as a producing or depleted oil well or gas well, or such as a geothermal water well, or such as hot dry rock; and, method of air-lift pumping water; and, method of electrolyzing the water into hydrogen and oxygen using the electricity genarated

(76) Inventor: Robert Daniel Hunt, Pass Christian, MS (US)

Correspondence Address: Robert Daniel Hunt, 23707 Redfish Lane, Pass Christian, MS, 39571, US

(21) Appl. No.: 09/906,951

(22) Filed: Jul. 16, 2001

(51) Int. Cl. C02F 1/461; H01L 35/34; H01L 37/00; H01L 35/28; H01L 35/02

(52) U.S. Cl. 205/742; 136/222; 136/230

(57) ABSTRACT

The present invention relates to generation of electricity by high-pressure, high-enthalpy cryogenic vapor formed by absorption of heat from a geothermal heat source. The cryogen is injected into a U-tube or an open tube heat exchanger extending to the bottom of a geothermal well and thermal energy is gained by the cryogen, causing the cryogen to vaporize into high-enthalpy cryogenic vapor that returns to the surface to power a rotary vane motor that drives an electrical generator. Also, electricity is generated by a geothermal thermoelectric generator placed either underground or above ground using heat extracted from the bottom of the geothermal well via a U-tube or an open tube heat exchanger. The cryogenic vapor is capable of air-lift pumping water from the well. The electricity generated may be used to electrolyze the water into hydrogen and oxygen.

### CROSS REFERENCE TO RELATED APPLICATIONS

Related U.S. patent applications by the Present Applicant, Robert D. Hunt, Customer Number 27531: Titled, “The Production of Electricity Via the High-Pressure Injection a Cryogen into a Geothermal Thermoelectric Generator within a Geothermal Heat Source, such as a Producing or Depleted Oil Well or Gas Well, or such as a Geothermal Water Well, or such as Hot Dry Rock”; and, titled, “Cryogen Production Via a Cryogenic Vapor Driven Power Piston for use in a Cryogenic Vapor Powered Vehicle with Rotary Vane Motors Attached to the Axles of the Vehicle next to the Vehicle's Four Wheels, Using a Heat Source such as Solar Heat, Heat of Compression (Heat Pump or Air Compressor, etc.) or Heat of Friction (as Formed by an Electric Generator) or Chemical Heat, or Heat Formed by Electrical Resistance, Heat of Combustion, etc. to Generate High-Pressure, High-Kinetic Energy Cryogenic Vapor” Application Number jc978 U.S. PTO 09/873983 dated Jun. 4, 2001; and, titled “Thermoelectric Vaporizer for the Efficient Generation of Electricity Thermoelectrically and for the Simultaneous Vaporization of a Cryogen” Application Number jc996 U.S. PTO 09/877781 dated Jun. 11, 2001; and, titled, “Method of Cryogen Production and Thermoelectric Solid-State Electric Power Generation whereby the Thermal Energy of the Atmosphere is Directly Converted to Electrical Power and whereby the Thermal Energy of the Atmosphere is used to Produce High-Energy Cryogenic Vapor Capable of Performing Substantial Work and Pure Water is Produced from Water Vapor within the Atmosphere” Application Number j1002 U.S. PTO 09/883466 dated Jun. 18, 2001; and, titled, “Solid Oxide or Solid Acid High-Temperature Steam Electrolyzer Constructed in Alternating Layers of P-Type, N-Type, and Solid Oxide or Solid Acid Materials for the Self-Generation of Electricity Thermoelectrically for Electrolysis of High-Temperature Steam into Hydrogen and Oxygen”; and, titled, “Cryogen Production and Cryogenic Heating and Cooling Device Constructed Therefrom”; and, titled, “The Burning of Disassociated Water as a Direct Fuel Via a Hydrogen Thermolysis Reactor, which Sustains . . . ” application Ser. No. 09/774,110 dated Jan. 31, 2000.

### COPYRIGHT STATEMENT The Author of the Patent Application is Robert Daniel Hunt, 23707 Redfish Lane, Pass Christian, Miss. 39571. Telephone (228) 452-7917, E-mail: huntband@aol.com

### BACKGROUND OF INVENTION

Geothermal power generation has been in use for many years. The most common method of geothermal power generation is to drill a geothermal well into the earth at a site with geothermal heat and with water close to the earth's surface, which allows hot water or steam to rise to the surface. The hot water is flashed to steam or the steam that exits from the well drives a steam turbine engine and electric generator to produce electricity.

A great deal of research is being performed in an effort to generate electricity from the heat contained from hot dry rock. Geothermal heat may be found nearly everywhere within the earth at significant depth. However, few sites provide shallow geothermal heat and water pockets located at the same site as is required for steam production as used by the prior art. In some instances water is injected into the hot dry rock to produce steam for electric power generation, but large amounts of water are required to operate the process and the results are often poor.

Several significant problems exist within the industry as practiced by the prior art. The geothermal water and/or steam is often contaminated with minerals derived from the earth that dissolve into the water of the geothermal well. Often these substances are extremely corrosive and produce scale and mineral deposits which rust and foul equipment. Also, evaporation is a problem both as a water loss and as a heat loss as the latent heat of evaporation may consume a significant amount of the heat that is produced by the geothermal well

Geothermal power production, as used in the prior art, has many limitations, such as finding sites where substantial heat within the earth is close to the surface and finding sufficient amounts of underground water that may be transformed into steam at the same site, use of specialized drilling and heat pump equipment, and drilling geothermal wells is very expensive.

Depleted and abandoned oil and gas wells often extend great distances into the earth and the temperature at the bottom of these wells is often very high. However, they are not considered suitable for geothermal power production as used in the prior art for a number of reasons, such as the depth is too great for steam production as the steam will condense into water again as it passes through the upper portion of the well which is generally substantially cooler than the temperature at the bottom.

Many oil and gas wells have substantial well diameters near the surface passing through the fresh water zone, then the diameters of most wells significantly reduce. Many abandoned oil and gas wells extend three to five miles underground where the heat is very substantial, but the diameter of the well at these depths is often much smaller than the diameter near the surface.

The production of oil and gas is a high risk-business enterprise with a low percentage of the wells drilled actually producing oil and gas. Also, a substantial amount of electrical current is required in the operation of oil and gas facilities.

This invention relates to the production of electricity by energy conversion of heat to electricity thermoelectrically by the use of the Peltier effect or the converse, the Seebeck effect. Hot and cold junctions connect dissimilar metals in a closed circuit and the EMF develops current in the circuit in a measure related to the temperature difference and rate of heat input or output.

U.S. Pat. No. 5,288,336 “Thermoelectric Energy Conversion”, Strachan et al. teaches us that thermoelectric power generation may be accomplished by using p-type and n-type materials in alternating layers with a cold source on one side of the layers of material and a heat source on the opposite side of the layers of material with the heat being able to conduct through the layers of material parallel to the p/n junctions of the material and with an alternating current to prevent the formation of cold spots to generate electricity more efficiently, creating a solid-state generator.

U.S. Pat. No. 5,288,336 also teaches us that base metals, such as aluminum and nickel, with high electrical and thermal conductivity may be used to efficiently generate electricity thermoelectrically by use of fast cycling A.C. current to prevent cold spot formation. Also, micro-thin layers of p-type and n-type materials are used of such small thickness, 200 angstrom aluminum and 400 angstrom nickel, that the electrical conductivity is greatly increased relative to the thermal conductivity.

U.S. Pat. No. 5,288,336 claims an extremely high efficiency using micro-thin layers of alternating aluminum and nickel, conductive base materials, of in excess of three hundred micro-volts per deg. C. with a net energy conversion efficiency well above forty-six percent (46%) of that set by the Carnot Limit.

Thermoelectric devices in general have a low efficiency, usually with less than ten percent (10%) conversion of heat to electricity, because much of the heat is thermally conducted across the materials used that becomes heat loss and is not converted to electricity.

Thermoelectric devices are most commonly made of bismuth telluride and new research is showing great promise for thermoelectric devices constructed of the quantum well technique of micro-thin layers ranging from 10 to 100 angstrom thick of such materials as silicon/silicon germanium (Si/SiGe), boron carbon alloys (B4C/B9C). These quantum well materials have yielded as much as 4 times higher efficiency than conventional thermoelectric modules whose legs are fabricated from bulk materials.

U.S. Pat. No. 6,199,317 titled “Cryogenic Thermoelectric Generator” by Volk teaches us that the production of electricity may be performed by use of a cryogenic thermoelectric solid-state generator. Electricity may be produced using cryogenics as the cold source for the cold-side of a thermoelectric device.

It may be noted that the applicant has filed U.S. Patent Application Serial Number jc978 U.S. PTO 09/873983 dated Jun. 4, 2001 currently pending for a method of producing a cryogen from the ambient temperature air of the atmosphere, titled, “Cryogen Production Via a Cryogenic Vapor Driven Power Piston for use in a Cryogenic Vapor Powered Vehicle with Rotary Vane Motors Attached to the Axles of the Vehicle next to the Vehicle's Four Wheels, Using a Heat Source such as Solar Heat, Heat of Compression (Heat Pump or Air Compressor, etc.) or Heat of Friction (as Formed by an Electric Generator) or Chemical Heat, or Heat Formed by Electrical Resistance, Heat of Combustion, etc. to Generate High-Pressure, High-Kinetic Energy Cryogenic Vapor”.

It may be noted that the applicant has filed a patent application currently pending for patent protection on a second method of producing a cryogen from the ambient temperature air within the atmosphere and on a method of generating electricity thermoelectrically from the thermal energy (heat) contained within the atmosphere, titled, “Method of Cryogen Production and Thermoelectric Solid-State Electric Power Generation whereby the Thermal Energy of the Atmosphere is Directly Converted to Electrical Power and whereby the Thermal Energy of the Atmosphere is used to Produce High-Energy Cryogenic Vapor Capable of Performing Substantial Work and Pure Water is Produced from Water Vapor within the Atmosphere”

It may be noted that the applicant has filed a U.S. Patent Application Serial Number jc996 U.S. PTO 09/877781 dated Jun. 11, 2001 currently pending on a method of producing electricity thermoelectrically via a thermoelectric vaporizer, titled, “Thermoelectric Vaporizer for the Efficient Generation of Electricity Thermoelectrically and for the Simultaneous Vaporization of a Cryogen”.

It may be noted that the applicant has filed a U.S. patent application currently pending on a method of generating electricity using the heat of a geothermal well.

Electricity is generated by a geothermal thermoelectric generator that directly transforms heat into electricity thermoelectrically and electricity is also generated by use of high-pressure, high-enthalpy cryogenic vapor to power a rotary vane motor to drive an electrical generator titled, “The Production of Electricity Via the High-Pressure Injection of a Cryogen into a Geothermal Thermoelectric Generator within a Geothermal Heat Source, such as a Producing or Depleted Oil Well or Gas Well, or such as a Geothermal Water Well, or such as Hot Dry Rock”

It is an object of the present patent application to beneficially use the heat loss inherent in thermoelectric power generation due to thermal conduction to vaporize a cryogen and to thus improve on the process of the prior art patents in the efficient use of heat from a geothermal source.

It is an object of the present invention to produce a geothermal well technology that generates more electrical power than may be generated by prior art geothermal technologies.

It is also an object of the present invention to introduce a very clean geothermal technology that does not interact directly with the ground water of the earth and, therefore, does not produce corrosive substances and mineral deposits.

It is an object of the present invention to provide a method and apparatus capable of producing electricity from a geothermal source that may be used in almost any location worldwide.

It is an object of the present invention to provide a method and apparatus to generate electricity using producing or depleted oil wells or gas wells or using flowing geothermal water wells.

It is an object of the present invention to reduce the risks associated with oil and gas exploration.

It is an object of the present invention to locate the thermoelectric generator near the surface within the surface casing or on the surface itself and to utilize the greater degree of heat at the bottom of a geothermal well by use of a heat exchange U-tube or open tube having cryogenic vapor flowing through the tube to act as a transfer medium to transfer heat from the bottom of the geothermal well to the geothermal thermoelectric generator located at the upper portion of the well or located on the surface above the geothermal well.

It is an object of the present invention to pump water from a geothermal well using air-lift pumping powered by high-pressure cryogenic vapor.

It is an object of present invention to use the heat contained in the water pumped from the well to generate electricity thermoelectrically.

It is an object of the present invention to use the water pumped from the well in association with the use of the electricity generated by the geothermal thermoelectric generator and use of the electricity generated by an electrical generator powered by high-pressure, high-enthalpy cryogenic vapor to electrolyze the water into hydrogen and oxygen via high-temperature steam electrolysis using a solid-oxide electrolyzer.

### SUMMARY OF INVENTION

The present invention provides a method and apparatus for the production of electricity using a geothermal heat source and using the air within the earth's atmosphere as the working fluid. Atmospheric air is reduced in temperature and specific volume until it is transformed into an air cryogen. A cryogen is defined as a substance with a temperature below −150 C. The super-cold liquid cryogen is injected into a geothermal well through a U-tube or open tube heat exchanger and passes through the center of a thermoelectric generator forming the generator's cold-side. The U-tube or open tube may extend to the bottom of the geothermal well after passing through the center of thermoelectric generator.

The cryogen within the U-tube or open tube is vaporized by the heat within the well and the cryogenic vapor flows through the U-tube or open tube to the bottom of the geothermal well. The open tube is open at the bottom of the well and the cryogenic vapor flows directly into the well. The cryogenic vapor returns to the thermoelectric generator within the closed U-Tube and the hot cryogenic vapor flows directly through the outer portion of the generator within cryogenic vapor return ports to deliver heat from the bottom of the well to form the hot-side of the thermoelectric generator. The open tube allows the cryogenic vapor to return to the surface by passing between the thermoelectric generator and the well casing and heat is transferred to the outer portion of the thermoelectric generator to form the hot-side of the thermoelectric generator via the hot cryogenic vapor as it passes the generator on its way back to the surface.

If the geothermal well is partially filled with water, an open tube will cause the high-pressure cryogenic vapor to be injected into the water at the bottom of the well and the cryogenic vapor will air-lift pump water from the well. The water may be used for many useful purposes, such as agriculture, manufacturing, and for drinking if potable. In the event the water is saline, it may be desirable to inject the water back into the earth via an injection well.

One of the potential uses of the water from the well, possibly fresh or saline water, is to produce hydrogen and oxygen via high-temperature steam electrolysis of the water using the electricity produced by the geothermal thermoelectric generator as a source of electricity to perform electrolysis of water into hydrogen and oxygen.

Heat to produce steam may be obtained by using an electrical resistance heating unit or may be obtained by combusting a portion of the hydrogen and oxygen produced to heat water into steam. The steam would separate from the minerals dissolved in the water and distilled water in the form of steam would be electrolyzed into hydrogen and oxygen. The remaining minerals may have value as useful and valuable chemicals

The geothermal thermoelectric generator is a solid-state generator that is inserted into a geothermal well that could possibly extend from the surface of the earth to the bottom of the geothermal well. However, may wells only have substantial diameters near the surface passing through the fresh water zone and usually the diameter significantly reduces thereafter. Many abandoned oil and gas wells extend three to five miles underground where the heat is very substantial. In order to locate the geothermal thermoelectric generator in the surface casing and in order to obtain the heat of the bottom of the well a U-tube or an open tube extending to the bottom of the well may be used as bottom hole heat exchangers.

The electrical power generation capability of a thermoelectric generator located at or near the surface with a U-tube or open tube heat exchanger extending to the bottom of a geothermal well three miles long transferring heat back to the thermoelectric generator from the bottom of the well may be very great indeed. Electrical power is also generated at the surface by the high-pressure cryogenic vapor that returns from the bottom of the thermoelectric generator after having received heat from the earth that substantially increases the internal energy and the enthalpy of the cryogenic vapor. Also, other forms of mechanical drive may be powered by the high enthalpy cryogenic vapor, including air-lift pumping of water or oil and pneumatic forms of work that use pressurized air.

The apparatus of the present invention may be installed in new oil and gas wells during the drilling process to reduce the risk associated with drilling an oil and/or gas well. If the oil or gas well does not become a producing well, the electricity generated by the thermoelectric generator will provide a substantial income from the sale of electrical power that will result in a substantial return on investment.

The cryogen is pumped into the geothermal well as a cold-liquid that requires very little energy to pump to high-pressure. The pressure of the cryogen must be sufficient to overcome the pressure within the geothermal well in order to force the cryogen into the well. An estimate of the increase in ground pressure is that there is an increase in pressure of one pound per square inch of pressure for each two feet below the earth's surface. Therefore, a ten thousand feet deep geothermal well would have a bottom pressure of near 5,000 p.s.i.

To force cryogen to the bottom of the well in a U-tube or open tube heat exchanger, a greater cryogen pumping pressure is required than the pressure at the bottom of the well. The temperature of the earth varies by location, but by general rule a temperature increase of one degree F. may be anticipated for every sixty feet of depth. Assuming a surface temperature of 77 F. (25 C.), a ten thousand feet deep geothermal well may have a bottom temperature of near 244 F. (118 C.), calculated as 10,000 feet divided by 60 feet equals 167 F. (75 C.) plus the surface temperature of 77 F. (25 C.). Using the above example, the cryogen that exits an open tube at the bottom of the geothermal well would have a pressure greater than 5,000 p.s.i. and a U-tube will have an internal pressure exceeding 5,000 p.s.i.

At specific geothermal sites, temperatures may exceed 350 C. at depths less than a thousand feet. Heat absorbed from the earth by the liquid cryogen will cause the cryogen to vaporize into cryogenic vapor and the pressure of the cryogenic vapor will be greater than the pressure of the cryogen. Still further heating will cause the cryogenic vapor to expand and will cause the pressure to increase as thermal energy is gained. The internal energy of the cryogenic vapor is increased and thus the enthalpy of the cryogenic vapor is increased (h=u+pv). The heating of the cryogen causes the liquid to transform into a gas, energetic cryogenic vapor, that is on the order of a thousand times greater in volume than that of the liquid, and the pressure of the cryogenic vapor exceeds the pressure of the liquid cryogen. The volume and pressure of the cryogenic vapor may be increased in relationship to the amount of thermal energy input into it. The amount of work that the hot, expanded, and pressurized cryogenic vapor can do is in direct relationship to the amount of thermal energy it contains. The heat is the source of the kinetic energy in the cryogenic vapor and the more heat (thermal energy) that is absorbed by the cryogenic vapor; the greater the work that can be performed by the cryogenic vapor.

In the event that the generator is located near the surface or on the surface, a U-Tube closed heat exchange loop or a open ended tube will return heat from the bottom of the geothermal well upward to the generator. Alternately, the kinetic energy produced by a geothermal well may be used to operate a rotary vane motor at the surface without use of a thermoelectric generator.

Many factors will determine the exact results which will vary according the conditions of each geothermal well such as depth, casing sizes, bottom temperature, the volume of cryogen forced into the bottom of the geothermal well within a U-tube or open tube, etc. However, it is reasonable to assume that tremendous volumes of gas at enormous pressures may be accomplished using the above described method of the present patent.

The present patent application presents two methods for the generation of electricity: thermoelectrically and mechanically by use of kinetic force to drive an electric generator via a rotary vane motor, bladeless turbine, expansion turbine, etc.

Thermoelectric power generation may be conducted within the geothermal well itself. The geothermal thermoelectric generator is inserted into the well. The thermoelectric generator is constructed of alternating layers of P-type and N-type materials capable of generating electricity thermoelectrically with the heat of the earth (hot-side) on one side of the layers of material and with the cryogen (cold-side) on the other side of the layers of material to create a temperature differential. As heat conducts through the layers of material, a portion of the heat is directly converted to electricity thermoelectrically.

The thermoelectric generator may not be of great length and may not extend to the bottom of the well and may be located at or near the surface of the well. In such event heat will be returned to the generator via a U-tube heat exchanger of via an open tube heat exchanger. The open tube heat exchanger may air-lift pump water from the well if the water table is sufficiently close enough to the surface. The water may have substantial heat energy available that may be converted to electricity thermoelectrically

Water air-lift pumped from a well may be used for many uses, including for human consumption if the water is potable, for agriculture or aquaculture, and for manufacturing processes.

Salt water may be used for hydrogen and oxygen production via high-temperature steam electrolysis using the electricity generated by the geothermal thermoelectric generator or by an electrical generator at the surface. Heat for the process may be obtained by combusting a portion of the hydrogen and oxygen produced or may be obtained by heat created by a resistance electrical heating coil.

The present invention may be used to generate electricity thermoelectrically using depleted, abandoned oil wells via the heat within them or may be installed in new oil and gas wells during the drilling process to produce commercial amounts of electricity, thus reducing the risk associated with oil and gas exploration. Wells may be drilled at almost any site worldwide for the specific purpose of installation of geothermal thermoelectric generators for the generation of electricity thermoelectrically using the heat within the earth, including hot dry rock formations.

Also, the present invention may be used to generate electricity at the surface using an electric generator, powered by the high-pressure, high-enthalpy, energetic cryogenic vapor retuning from a geothermal well driving a rotary vane motor.

### BRIEF DESCRIPTION OF DRAWINGS

FIG. 1 describes a U-tube shaped geothermal heat exchanger in which a cryogen is injected. The cryogen is vaporized and further heated until it becomes high-pressure, high-enthalpy cryogen vapor. Electricity is generated by an electric generator at the surface powered by the energetic cryogenic vapor driving a rotary vane motor.

FIG. 2 describes an open tube geothermal heat exchanger in which a cryogen is injected. The cryogen is vaporized and further heated until it becomes high-pressure, high-enthalpy cryogen vapor. The cryogenic vapor is allowed to exit the open tube and to flow into the geothermal well itself. The cryogenic vapor rises to the surface and air-lift pumps water from the well. At the surface electricity is generated by an electric generator powered by the energetic cryogenic vapor and by the hot water air-lifted from the well that drives a rotary vane motor.

FIG. 3 describes a U-tube shaped geothermal heat exchanger in which a cryogen is injected. The cryogen is vaporized and further heated until it becomes high-pressure, high-enthalpy cryogen vapor. Electricity is generated by an electric generator at the surface powered by the energetic cryogenic vapor driving a rotary vane motor. Electricity is also generated by a Geothermal Thermoelectric Generator that uses the heat of the earth as its hot-side and the cryogen injected into the U-tube as its cold-side. The cryogen passes to the bottom of the well within the U-tube and is heated by heat exchange of the greater heat deep within the earth and returns to the geothermal thermoelectric generator to transfer heat to the generator so that the heat may be converted to electricity thermoelectrically.

FIG. 4 describes an open tube geothermal heat exchanger in which a cryogen is injected. The cryogen is vaporized and further heated until it becomes high-pressure, high-enthalpy cryogen vapor. Electricity is generated by an electric generator at the surface powered by the energetic cryogenic vapor driving a rotary vane motor. Electricity is also generated by a Geothermal Thermoelectric Generator located on the surface that uses heat transferred to the generator by the returning hot cryogenic vapor and hot water air-lift pumped from the geothermal well. Cryogen passes through the thermoelectric generator on the surface and then passes to the bottom of the well within the open tube and is heated by heat exchange with the greater heat deep within the earth. The cryogenic vapor is allowed to exit the open tube and to flow into the geothermal well itself. The cryogenic vapor rises to the surface and air-lifts water from the well. At the surface heat is transferred to the thermoelectric generator's hot-side as the hot cryogenic vapor and hot water flow past the generator so that the heat may be converted to electricity thermoelectrically.

FIG. 5 describes an open tube geothermal heat exchanger in which a cryogen is injected. The cryogen is vaporized and further heated until it becomes high-pressure, high-enthalpy cryogen vapor. Electricity is generated by an electric generator at the surface powered by the energetic cryogenic vapor driving a rotary vane motor. Electricity is also generated by a Geothermal Thermoelectric Generator that uses the heat of the earth as its hot-side and the cryogen injected into the open tube as its cold-side. The cryogen passes to the bottom of the well within the open tube and is heated by heat exchange of the greater heat deep within the earth. The cryogenic vapor is allowed to exit the open tube into the geothermal well itself. The cryogenic vapor air-lifts water from the well as it rises toward the surface. The cryogenic vapor and water pass through the space between the well casing and the outside of the geothermal thermoelectric generator as they flow to the surface. Heat is transferred from the hot water and hot cryogenic vapor to the generator's hot-side as the hot cryogenic vapor and hot water flow past the outer portion of the generator so that the heat may be converted to electricity thermoelectrically. At the surface the water is separated from the cryogenic vapor. The water may be used for beneficial purposes, such as agriculture, aquaculture, and manufacturing and may be used for human consumption if the water is potable.

FIG. 6 describes an open tube geothermal heat exchanger in which a cryogen is injected. The cryogen is vaporized and further heated until it becomes high-pressure, high-enthalpy cryogen vapor. Electricity is generated by an electric generator at the surface powered by the energetic cryogenic vapor driving a rotary vane motor. Electricity is also generated by a geothermal thermoelectric generator that uses the heat of the earth as its hot-side and the cryogen injected into the open tube as its cold-side. The cryogen passes to the bottom of the well within the open tube and is heated by heat exchange of the greater heat deep within the earth. The cryogenic vapor is allowed to exit the open tube into the geothermal well itself.

The cryogenic vapor air-lift pumps water from the well as it rises toward the surface. The cryogenic vapor and water pass through the space between the well casing and the outside of the geothermal thermoelectric generator as they flow to the surface. Heat is transferred from the hot water and hot cryogenic vapor to the generator's hot-side as the hot cryogenic vapor and hot water flow past the outer portion of the generator so that the heat may be converted to electricity thermoelectrically. At the surface the water is separated from the cryogenic vapor. The water is injected into an injection well to be returned to the earth. In most cases requiring disposal of the water, the water will be highly saline and of no economic value.

FIG. 7 describes an open tube geothermal heat exchanger in which a cryogen is injected. The cryogen is vaporized and further heated until it becomes high-pressure, high-enthalpy cryogen vapor. Electricity is generated by an electric generator at the surface powered by the energetic cryogenic vapor driving a rotary vane motor. Electricity is also generated by a geothermal thermoelectric generator that uses the heat of the earth as its hot-side and the cryogen injected into the open tube as its cold-side. The cryogen passes to the bottom of the well within the open tube and is heated by heat exchange of the greater heat deep within the earth. The cryogenic vapor is allowed to exit the open tube into the geothermal well itself. The cryogenic vapor air-lift pumps water from the well as it rises toward the surface. The cryogenic vapor and water pass through the space between the well casing and the outside of the geothermal thermoelectric generator as they flow to the surface. Heat is transferred from the hot water and hot cryogenic vapor to the generator's hot-side as the hot cryogenic vapor and hot water flow past the outer portion of the generator so that the heat may be converted to electricity thermoelectrically.

At the surface the water is separated from the cryogenic vapor and is used to provide water to a high-temperature, solid oxide electrolyzer to electrolyze the water into hydrogen and oxygen using the electricity generated by the electrical generator at the surface and by the geothermal thermoelectric generator within the geothermal well. A portion of the hydrogen produced is combusted to provide heat for the production of steam and to maintain the operating temperature of the solid oxide electrolyzer which is approximately 1,200 C.

### DETAILED DESCRIPTION

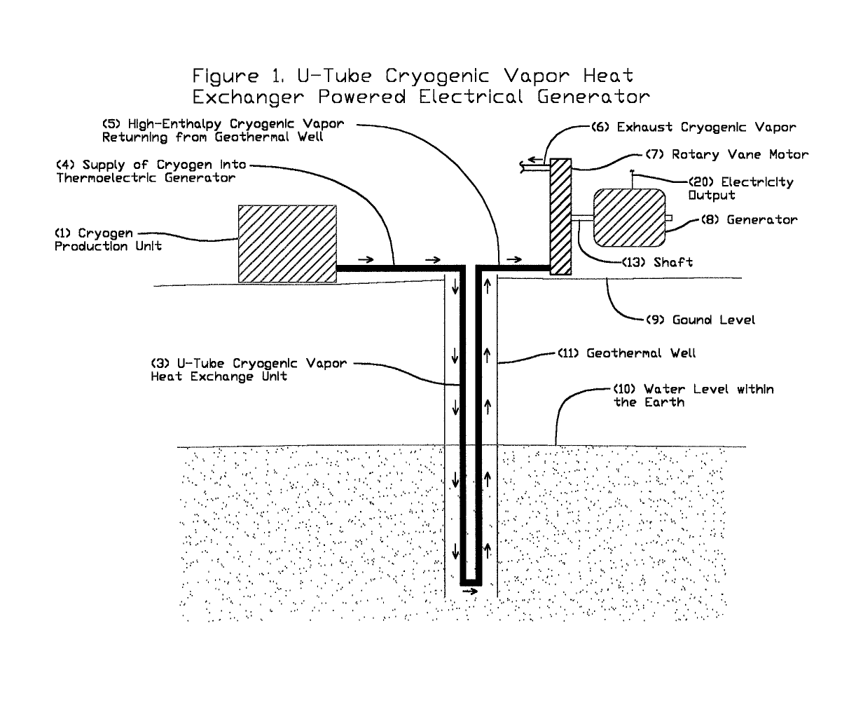

FIG. 1 describes a U-tube shaped geothermal heat exchanger (3) in which a cryogen is injected (4). The cryogen (4) is produced by a cryogen production unit (1) that reduces air within the atmosphere into a super-cold liquid cryogen (4). The U-tube (3) is inserted into a geothermal well (11). As the cold cryogen (4) passes through the U-tube (3) it receives heat transferred from the thermal energy of the earth within the geothermal well (11) and is vaporized into cryogenic vapor (5). The cryogenic vapor (5) formed from the vaporized cryogen (4) is further heated as it passes through the U-tube (3) deeper into the earth within the geothermal well (11 ) where the heat is greater.

Usually there is a water level (10) at some depth within the earth. The hot and often saline water below the water level (10) has a great ability to transfer additional heat to the cryogenic vapor (5) within the U-tube (3). Upon further heating, the cryogenic vapor (5) becomes high-pressure, high-enthalpy cryogenic vapor (5). The high-pressure, high-enthalpy cryogenic vapor (5) returns to the surface of the earth at ground level (9) and generates electricity (20) via an electric generator (8) that is driven by a rotary vane motor (7) connected to the generator (8) by a shaft (13). The rotary vane motor (7) is powered by the energetic cryogenic vapor (5). The spent cryogenic vapor (5) is exhausted (6) from the rotary vane motor (7) back into the atmosphere in which the cryogen (4) was produced from.

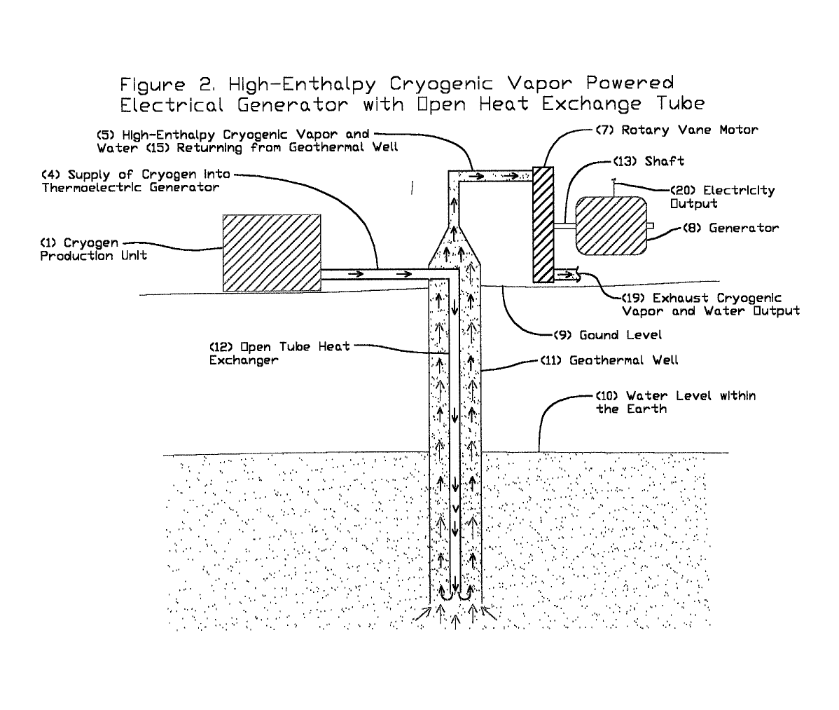

FIG. 2 describes an open geothermal heat exchange tube (12) in which a cryogen (4) is injected. The cryogen (4) is produced by a cryogen production unit (1) that reduces air within the atmosphere into a super-cold liquid cryogen (4). The open tube (12) is inserted into a geothermal well (11). As the cold cryogen (4) passes through the open heat exchange tube (12) it receives heat transferred from the thermal energy of the earth within a geothermal well (11) and is vaporized into cryogenic vapor (5). The cryogenic vapor (5) is allowed to exit the open tube (12) and to flow into the geothermal well (11) itself. Usually there is a water level (10) at some depth within the earth. The hot and often saline water below the water level (10) has a great ability to transfer additional heat to the cryogenic vapor (5) inside of the geothermal well (11). The cryogenic vapor (5) rises to the surface and air-lift pumps water (15) from the geothermal well (11). The cryogenic vapor (5) is further heated until it becomes high-pressure, high-enthalpy cryogenic vapor (5). At the surface above ground level (9), electricity (20) is generated by an electric generator (8) powered by the energetic cryogenic vapor (5) and by the hot water (15) air-lifted from the well (11) that drives a rotary vane motor (7) connected to the generator (8) by a shaft (13). The spent cryogenic vapor (5) and water (15) are allowed to exit the rotary vane motor (7) by an exhaust cryogenic vapor and water outlet (19).

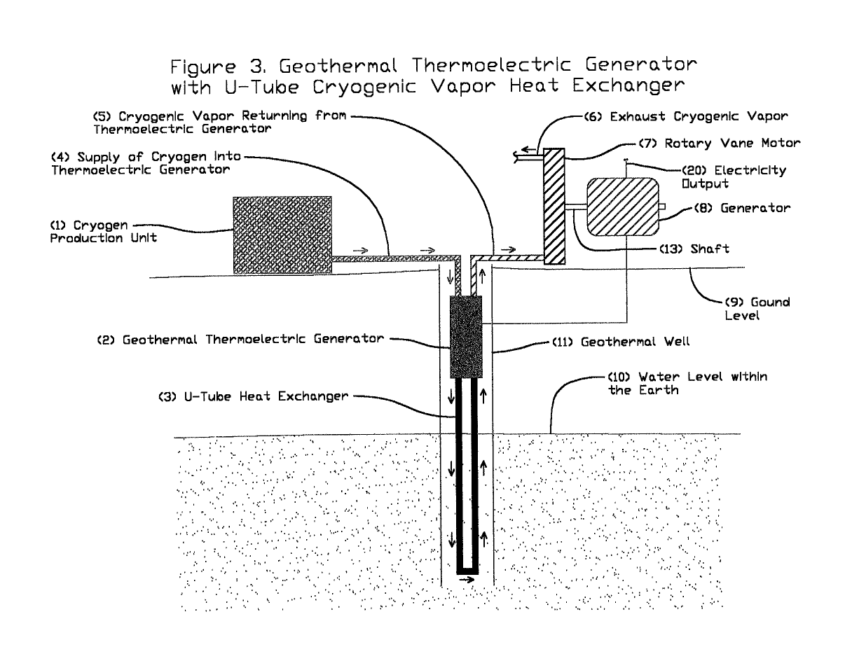

FIG. 3 describes a U-tube shaped geothermal heat exchanger (3) in which a cryogen is injected (4). The cryogen (4) is produced by a cryogen production unit (1) that reduces air within the atmosphere into a super-cold liquid cryogen (4). The U-tube (3) is inserted into a geothermal well (11). The U-tube (3) with the cryogen (4) flowing through the U-tube (3) passes through a geothermal thermoelectric generator (2) and becomes the cold-side of the generator (2) with the heat within the geothermal well (11) being the hot-side of the generator (2). As the cold cryogen (4) passes through the U-tube (3) it receives heat transferred from the thermal energy of the earth within a geothermal well (11) and is vaporized into cryogenic vapor (5). The cryogenic vapor (5) formed from the vaporized cryogen (4) is further heated as it passes through the U-tube (3) deeper into the earth within the geothermal well (11) where the heat is greater.

Usually there is a water level (10) at some depth within the earth. The hot and often saline water below the water level (10) has a great ability to transfer additional heat to the cryogenic vapor (5) within the U-tube (3). Upon further heating, the cryogenic vapor (5) becomes high-pressure, high-enthalpy cryogenic vapor (5). The high-pressure, high-enthalpy cryogenic vapor (5) rises toward the surface within the U-tube (3) after passing the bottom of the geothermal well (11) and when the vapor (5) reaches the geothermal thermoelectric generator (2) it passes through the outer portion of the generator (2) and transfers heat from the bottom of the geothermal well (11) to the hot-side of the thermoelectric generator (2).

The high-pressure, high-enthalpy cryogenic vapor (5) returns to ground level (9) after passing through the thermoelectric generator (2) and generates electricity (20) via an electric generator (8) that is driven by a rotary vane motor (7) that is powered by the energetic cryogenic vapor (5). The generator (8) is connected to the rotary vane motor (7) by a shaft (13). The spent cryogenic vapor (5) is exhausted (6) from the rotary vane motor (7) back into the atmosphere in which the cryogen (4) was produced from.

The geothermal thermoelectric generator (2) is a solid-state device constructed of alternating layers of P-type and N-type materials. Heat is directly converted to electricity as it moves across dissimilar materials.

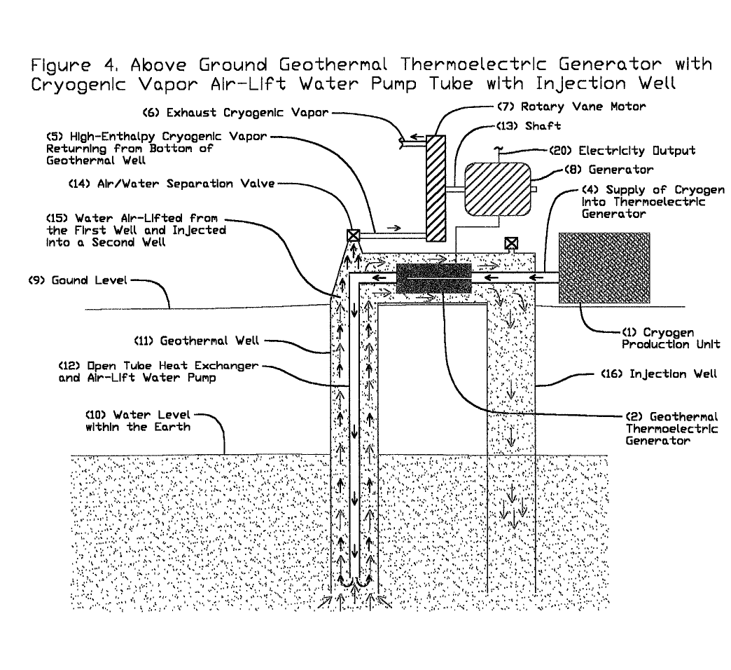

FIG. 4 describes an open tube heat exchanger (12) in which a cryogen (4) is injected. The cryogen (4) is produced by a cryogen production unit (1) that reduces air within the atmosphere into a super-cold liquid cryogen (4). The open tube heat exchanger (12) is inserted into a geothermal well (11). As the cold cryogen (4) passes through the open tube heat exchange (12) it receives heat transferred from the thermal energy of the earth within the geothermal well (11) and is vaporized into cryogenic vapor (5). The cryogenic vapor (5) is allowed to exit the open tube (12) and to flow into the geothermal well (11) itself. Usually there is a water level (10) at some depth within the earth. The hot and often saline water below the water level (10) has a great ability to transfer additional heat to the cryogenic vapor (5) inside of the geothermal well (11). The cryogenic vapor (5) rises to the surface and air-lifts water (15) from the geothermal well (11). The cryogenic vapor is further heated until it becomes high-pressure, high-enthalpy cryogenic vapor (5). At the surface above ground level (9), the cryogenic vapor (5) is separated from the water (15) by an air/water separation valve (14) and electricity (20) is generated by an electric generator (8) powered by the energetic cryogenic vapor (5) and by the hot water (15) air-lifted from the well (11) that drives a rotary vane motor (7) connected to the generator (8). The generator (8) is connected to the rotary vane motor (7) by a shaft (13). The spent cryogenic vapor (5) is exhausted (6) from the rotary vane motor (7) back into the atmosphere in which the cryogen (4) was produced from.

Electricity is also generated by a geothermal thermoelectric generator (2) located above ground level (9) that uses heat transferred to the generator (2) by the returning hot cryogenic vapor (5) and hot water (15) air-lifted from the geothermal well. Cryogen (4) passes through the thermoelectric generator (2) on the surface and then passes to the bottom of the well (11) within the open tube (12) and is heated by heat exchange with the greater heat deep within the earth inside the geothermal well (11). The cryogenic vapor (5) is allowed to exit the open tube (12) and to flow into the geothermal well (11) itself. The cryogenic vapor (5) rises to the surface and air-lift pumps water (15) from the well (11). At the surface heat is transferred to the thermoelectric generator's (2) hot-side as the hot cryogenic vapor (5) and hot water (15) flow past the outside of the generator (2) so that the heat may be converted to electricity thermoelectrically. The spend water (15) is injected into an injection well (16) and returned to the earth.

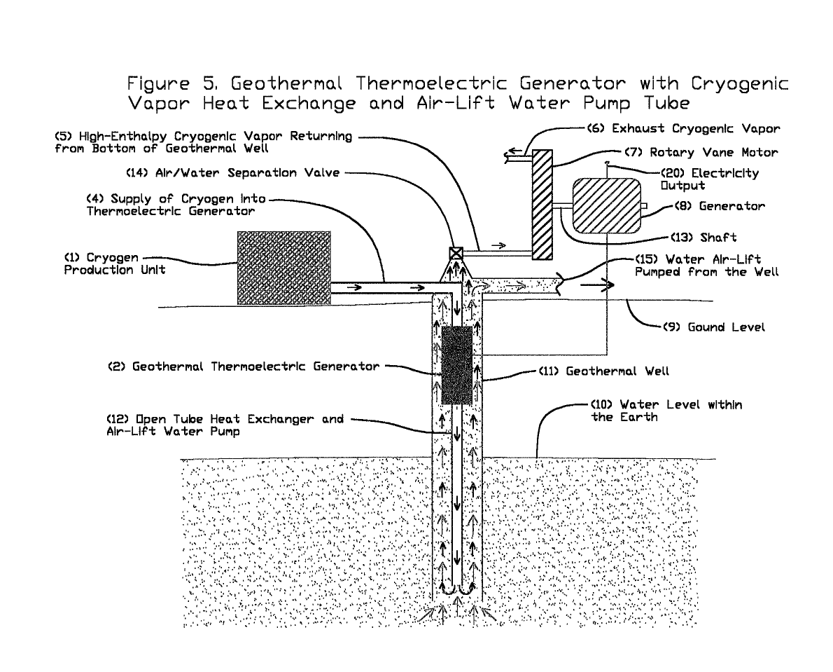

FIG. 5 describes an open tube geothermal heat exchanger (12) in which a cryogen (4) is injected. The cryogen (4) is produced by a cryogen production unit (1) that reduces air within the atmosphere into a super-cold liquid cryogen (4). The open tube heat exchanger (12) is inserted into a geothermal well (11). The open tube heat exchanger (12) with the cryogen (4) flowing through the tube (12) passes through the center of a geothermal thermoelectric generator (2) and becomes the cold-side of the generator (2) with the heat within the geothermal well (11) being the hot-side of the generator (2). As the cold cryogen (4) passes through the open tube heat exchanger (12) it receives heat transferred from the thermal energy of the earth within a geothermal well (11) and is vaporized into cryogenic vapor (5). The cryogenic vapor (5) formed from the vaporized cryogen (4) is further heated as it passes through the open tube heat exchanger (12) deeper into the earth within the geothermal well (11) where the heat is greater.

The cryogenic vapor (5) is allowed to exit the open tube (12) and to flow into the geothermal well (11) itself, which is usually flooded with water (15). Usually there is a water level (10) at some depth within the earth. The hot and often saline water below the water level (10) has a great ability to transfer additional heat to the cryogenic vapor (5) inside of the geothermal well (11). The cryogenic vapor (5) rises to the surface and air-lift pumps water (15) from the geothermal well (11). The cryogenic vapor is further heated until it becomes high-pressure, high-enthalpy cryogenic vapor (5). At the surface above ground level (9), the cryogenic vapor (5) is separated from the water (15) by an air/water separation valve (14) and electricity (20) is generated by an electric generator (8) powered by the energetic cryogenic vapor (5) that drives a rotary vane motor (7) connected to the generator (8) by a shaft (3). The spent cryogenic vapor (5) is exhausted (6) from the rotary vane motor (7) back into the atmosphere in which the cryogen (4) was produced from.

The cryogenic vapor (5) and hot water (15) air-lifted from the bottom of the geothermal well (11) pass through the space between the well casing and the outside of the geothermal thermoelectric generator (2) as they flow to the surface. Heat is transferred from the hot water (15) and hot cryogenic vapor (5) to the generator's (2) hot-side as the hot cryogenic vapor (5) and hot water (15) flow past the outer portion of the generator (2) so that the heat may be converted to electricity (20) thermoelectrically. The water (15) is separated from the cryogenic vapor (5) by a air/water separation valve (14). The water (15) may be used for beneficial purposes, such as agriculture, aquaculture, and manufacturing and may be used for human consumption if the water is potable.

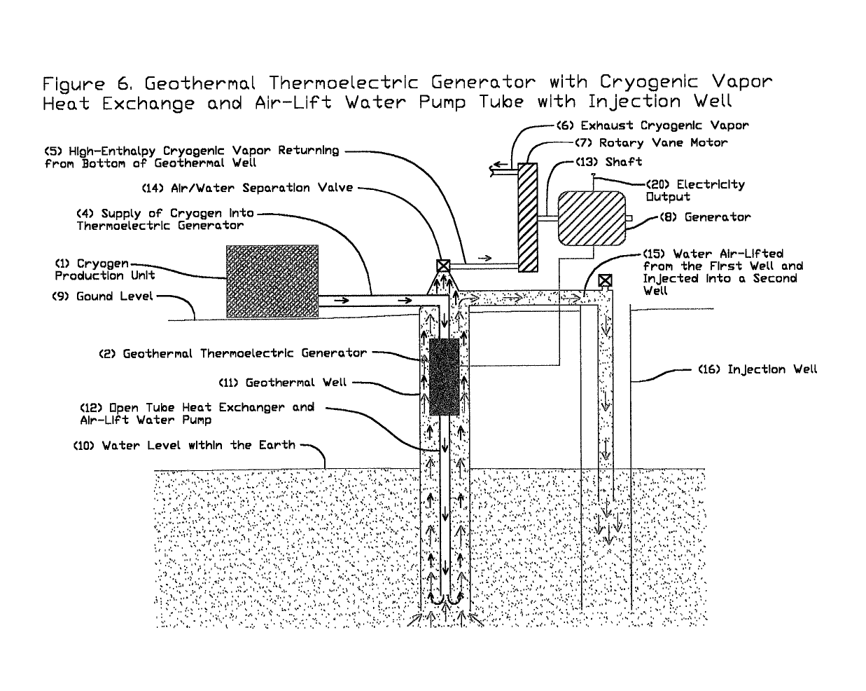

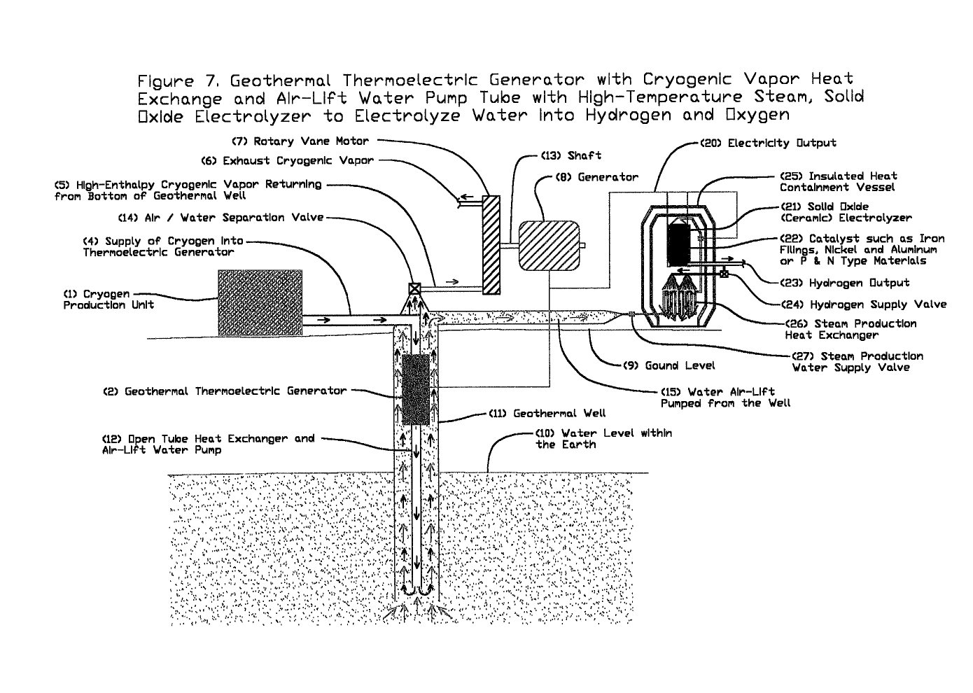

FIG. 6 describes an open tube heat exchanger (12) in which a cryogen (4) is injected. The cryogen (4) is produced by a cryogen production unit (1) that reduces air within the atmosphere into a super-cold liquid cryogen (4). The open tube heat exchanger (12) is inserted into a geothermal well (11). The open tube heat exchanger (12) with the cryogen (4) flowing through the tube (12) passes through the center of a geothermal thermoelectric generator (2) and becomes the cold-side of the generator (2) with the heat within the geothermal well (11) being the hot-side of the generator (2). As the cold cryogen (4) passes through the open tube heat exchanger (12) it receives heat transferred from the thermal energy of the earth within the geothermal well (11) and is vaporized into cryogenic vapor (5). The cryogenic vapor (5) formed from the vaporized cryogen (4) is further heated as it passes through the open tube heat exchanger (12) deeper into the earth within the geothermal well (11) where the heat is greater.

The cryogenic vapor (5) is allowed to exit the open tube (12) and to flow into the geothermal well (11) itself, which is usually flooded with water (15). Usually there is a water level (10) at some depth within the earth. The hot and often saline water below the water level (10) has a great ability to transfer additional heat to the cryogenic vapor (5) inside of the geothermal well (11). The cryogenic vapor (5) rises to the surface and air-lift pumps water (15) from the geothermal well (11). The cryogenic vapor is further heated until it becomes high-pressure, high-enthalpy cryogenic vapor (5). At the surface above ground level (9), the cryogenic vapor (5) is separated from the water (15) by an air/water separation valve (14) and electricity (20) is generated by an electric generator (8) powered by the energetic cryogenic vapor (5) that drives a rotary vane motor (7) connected to the generator (8) by a shaft (3). The spent cryogenic vapor (5) is exhausted (6) from the rotary vane motor (7) back into the atmosphere in which the cryogen (4) was produced from.

The cryogenic vapor (5) and hot water (15) air-lifted from the bottom of the geothermal well (11) pass through the space between the well casing and the outside of the geothermal thermoelectric generator (2) as they flow to the surface. Heat is transferred from the hot water (15) and hot cryogenic vapor (5) to the generator's (2) hot-side as the hot cryogenic vapor (5) and hot water (15) flow past the outer portion of the generator (2) so that the heat may be converted to electricity (20) thermoelectrically. The water (15) is separated from the cryogenic vapor (5) be an air/water separation valve (14) and the water (15) is injected into an injection well (16) to be returned to the earth. In most cases requiring disposal of the water (15), the water (15) will be highly saline and of no economic value.

FIG. 7 describes an open tube heat exchanger (12) in which a cryogen (4) is injected. The cryogen (4) is produced by a cryogen production unit (1) that reduces air within the atmosphere into a super-cold liquid cryogen (4). The open tube (12) is inserted into a geothermal well (11). The open tube heat exchanger (12) with the cryogen (4) flowing through the tube (12) passes through the center of a geothermal thermoelectric generator (2) and forms the cold-side of the generator (2) with the heat within the geothermal well (11) being the hot-side of the generator (2). As the cold cryogen (4) passes through the open tube heat exchanger (12) it receives heat transferred from the thermal energy of the earth within a geothermal well (11) and is vaporized into cryogenic vapor (5). The cryogenic vapor (5) formed from the vaporized cryogen (4) is further heated as it passes through the open tube heat exchanger (12) deeper into the earth within the geothermal well (11) where the heat is greater.

The cryogenic vapor (5) is allowed to exit the open tube (12) and to flow into the geothermal well (11) itself, which is usually flooded with water (15). Usually there is a water level (10) at some depth within the earth. The hot and often saline water below the water level (10) has a great ability to transfer additional heat to the cryogenic vapor (5) inside of the geothermal well (11). The cryogenic vapor (5) rises to the surface and air-lift pumps water (15) from the geothermal well (11). The cryogenic vapor is further heated until it becomes high-pressure, high-enthalpy cryogenic vapor (5). At the surface above ground level (9), the cryogenic vapor (5) is separated from the water (15) by an air/water separation valve (14) and electricity (20) is generated by an electric generator (8) powered by the energetic cryogenic vapor (5) that drives a rotary vane motor (7) connected to the generator (8) by a shaft (3). The spent cryogenic vapor (5) is exhausted (6) from the rotary vane motor (7) back into the atmosphere in which the cryogen (4) was produced from.

The cryogenic vapor (5) and hot water (15) air-lift pumped from the bottom of the geothermal well (11) pass through the space between the well casing and the outside of the geothermal thermoelectric generator (2) as they flow to the surface. Heat is transferred from the hot water (15) and hot cryogenic vapor (5) to the generator's (2) hot-side as the hot cryogenic vapor (5) and hot water (15) flow past the outer portion of the generator (2) so that the heat may be converted to electricity (20) thermoelectrically.

The water (15) allowed to pass through a water supply valve (27) is used to provide water (15) to a high-temperature, solid-oxide electrolyzer (21) made of ceramic material to electrolyze the water (15) into hydrogen and oxygen using the electricity (20) generated by the electrical generator (8) at the surface and by the geothermal thermoelectric generator (2) within the geothermal well. A small portion of the hydrogen produced is passed into a hydrogen line having a hydrogen supply valve (24) to supply hydrogen that is combusted to provide heat for the production of steam and to maintain the operating temperature required by the solid-oxide electrolyzer (21). The majority of the hydrogen produced is removed via a hydrogen outlet (24). The heat created by hydrogen combustion is directed to a steam production water heat exchanger (26) to form pressurized steam within the steam production heat exchanger (26) that is supplied to the solid-oxide electrolyzer (21). An insulated heat containment vessel (25) maintains the temperature sufficient for the efficient operation of the solid-oxide electrolyzer (21), which is approximately 1,200 C. Steam could be produced by use of an electrical resistance heating unit using electricity; however, it is more efficient to combust a small portion of the hydrogen and oxygen produced.

A catalyst (22) may help the electrolysis process to proceed more rapidly and efficiently. The catalyst (22) may consist of iron filings, nickel, aluminum, and layers of P and N type materials capable of generating electricity thermoelectrically, direct conversion of heat to electricity, to aid in the electrolysis process of disassociating water into hydrogen and oxygen.

Although the present invention has been described by reference to only a few embodiments thereof, it is to be understood that many changes and modifications may be readily derived by those skilled in the art, and it is intended by the appended claims that the scope of this invention is intended to cover all changes, modifications, uses and all new embodiments of the present invention that are in the spirit and scope of the invention.

1. A U-tube heat exchanger is hereby claimed.
It is claimed that a heat exchanger may be constructed in the form of a U; and,
it is claimed that the heat exchanger may be inserted into a geothermal heat source; and,
it is claimed that a geothermal heat source such as producing or depleted oil wells or gas wells and geothermal water wells often extend to great depths within the earth; and,
it is claimed that the U-tube heat exchanger may extend to the bottom of a geothermal heat source such as a geothermal well; and,
it is claimed that a working fluid may flow through the u shaped heat exchanger; and,
it is claimed that the working fluid may be water, a coolant, or may be a cryogen or cryogenic vapor; and,
it is claimed that the working fluid may absorb thermal energy in the form of heat from the geothermal source; and,
it is claimed that a cryogen within a U-tube heat exchanger may absorb thermal energy from the geothermal heat source; and,
it is claimed that the cryogen within a U shaped heat exchanger that absorbs thermal energy will transform into cryogenic vapor as the cryogen boils; and,
it is claimed that the cryogenic vapor will increase in enthalpy as it receives thermal energy for the geothermal heat source within the u shaped heat exchanger; and,
it is claimed that the cryogenic vapor will become high-pressure, high-enthalpy cryogenic vapor; and,
it is claimed that the hot cryogenic vapor within the U-tube can transfer heat absorbed at the bottom of the geothermal heat source to a geothermal thermoelectric generator located in the upper portion of the geothermal well or located at the surface.

2. An open tube shaped heat exchanger is hereby claimed.
It is hereby claimed that an open tube heat exchanger may be inserted into a geothermal heat source; and,
it is claimed that the open tube heat exchanger may extend to the bottom of a geothermal well; and,
it is claimed that a working fluid may flow through the open tube shaped heat exchanger; and,
it is claimed that the working fluid may be water, a coolant, or may be a cryogen or cryogenic vapor; and,
it is claimed that the working fluid may absorb thermal energy in the form of heat from the geothermal source; and,
it is claimed that the cryogen within the open tube heat exchanger that absorbs thermal energy will transform into cryogenic vapor as the cryogen boils; and,
it is claimed that the cryogenic vapor will increase in enthalpy as it receives thermal energy for the geothermal heat source within the open tube heat exchanger; and,
it is claimed that the cryogenic vapor will become high-pressure, high-enthalpy cryogenic vapor; and,
it is claimed that the cryogenic vapor will flow out of the open tube heat exchanger and into the geothermal well itself at the bottom of the well; and,
it is claimed that the cryogenic vapor will rise in the geothermal well and will air-lift water within the well if the water table is high enough; and,
it is claimed that the hot cryogenic vapor will transfer heat absorbed at the bottom of the geothermal heat source to a geothermal thermoelectric generator located in the upper portion of the geothermal well or located at the surface; and,
it is claimed that the hot water is capable of transferring heat to a geothermal thermoelectric generator located in the upper portion of the geothermal well or located at the surface; and,
it is claimed that the high-pressure, high enthalpy cryogenic vapor is capable of performing substantial work.

3. It is claimed that the high-pressure, high-enthalpy cryogenic vapor formed in the open tube heat exchanger of claim 2 is capable of air-lift (cryogenic vapor lift) pumping water from a geothermal well; and,
it is claimed that the cryogenic vapor formed in the open tube heat exchanger of claim 2 is capable of nitrogen-lift (cryogenic nitrogen vapor lift) pumping oil from an oil well.

4. A rotary vane motor, a central shaft, and an electric generator are hereby claimed.

5. It is claimed that the high-pressure, high enthalpy cryogenic vapor within the U-tube of claim 1 that returns to the surface through the U-tube may power a rotary vane motor of claim 4; and,
it is claimed that the rotary vane motor rotates a central shaft of claim 4 that mechanically drives an electric generator of claim 4 that generates electrical power.

6. It is claimed that the high-pressure, high enthalpy cryogenic vapor within the open tube of claim 2 that returns to the surface through the geothermal well may power a rotary vane motor of claim 4; and,
it is claimed that the rotary vane motor rotates a central shaft of claim 4 that mechanically drives an electric generator of claim 4 that generates electrical power; and,
it is claimed that the high-pressure, high enthalpy cryogenic vapor within the open tube of claim 2 that returns to the surface through the geothermal well may be separated from water air-lift pumped from the well before powering a rotary vane motor; and,
it is claimed that the high-pressure, high enthalpy cryogenic vapor within the open tube of claim 2 that returns to the surface through the geothermal well may be allowed to remain in solution with the water air-lift pumped from the well to power a rotary vane motor.

7. A geothermal thermoelectric generator is hereby claimed.

8. It is claimed that the geothermal thermoelectric generator of claim 7 may generate electricity thermoelectrically using the heat of the earth; and,
it is claimed that the geothermal thermoelectric generator of claim 7 may be used without the use of an electrical generator of claim 4 on the surface; and,
it is claimed that the electrical generator of claim 4 on the surface may be used without the use of a geothermal thermoelectric generator of claim 7. either within the geothermal heat source or located at the surface; and,
it is claimed that most thermoelectric devices are made of bismuth telluride; and,
it is claimed that bismuth telluride may be used to construct the thermoelectric generator of the present invention; and,
it is claimed that new research is showing great promise for thermoelectric devices constructed of the quantum well technique of micro-thin layers ranging from 10 to 100 angstrom thick of such materials as silicon/silicon germanium (Si/SiGe), boron carbon alloys (B4C/B9C); and,
it is claimed that the quantum well materials have yielded as much as four times higher efficiency than conventional thermoelectric modules whose legs are fabricated from bulk materials; and,
it is claimed that the quantum well technique of micro-thin layers ranging from 10 to 100 angstrom thick of such materials as silicon/silicon germanium (Si/SiGe), boron carbon alloys (B4C/B9C) may be used to construct the thermoelectric generator of the present invention; and,
it is claimed that the geothermal thermoelectric generator may be constructed in alternating layers of any P-type and N-type materials known, such as bismuth telluride, aluminum and nickel, silicon/silicon germanium (Si/SiGe), and boron carbon alloys (B4C/B9C); and,
it is claimed that the P-type and N-type layers may be of any thickness, including micro-thin quantum well materials of 10 angstrom or less; and,
it is claimed that the geothermal thermoelectric generator may be embodied in many different configurations that allow the hot-side and the cold-side to be separated by alternating layers of P-type and N-type materials, such as rows of alternating hot and cold separated by alternating layers of P-type and N-type materials, checker board squares of hot and cold separated by alternating layers of P-type and N-type materials, stacks of horizontal discs forming a vertical tubular shape consisting of alternating layers of P-type and N-type materials with a cold-side in the center of the tube and a hot-side outside of the discs; and,
it is claimed that the alternating layers of P-type and N-type materials may be positioned either vertically or stacked horizontally with a cold-side and with a hot-side on the opposite side of the alternating layers of P-type and N-type materials and opposite the cold-side.

9. It is claimed that high-pressure cryogen produced from the air in the atmosphere of the earth may be injected into the thermoelectric generator of claim 7 to form the cold-side of the generator; and,
it is claimed that the heat of the earth forms the hot-side of the generator.

10. It is claimed that the thermoelectric generator of claim 7 may be placed within any heat source; and,
it is claimed the thermoelectric generator may be placed within the earth to receive geothermal heat; and,

11. It is claimed that the thermoelectric generator of claim 7 may be placed below the ground level near the earth's surface and that heat from the bottom of a geothermal well may be transferred to the thermoelectric generator by the U-tube heat exchanger of claim 1 that may extend to the bottom of a geothermal well and may absorb a high-level of thermal energy; and,
it is claimed that the thermoelectric generator of claim 7 may be placed above ground level on the earth's surface and that heat from the bottom of a geothermal well may be transferred to the thermoelectric generator by the U-tube heat exchanger of claim 1. that may extend to the bottom of a geothermal well and may absorb a high-level of thermal energy.

12. It is claimed that the thermoelectric generator of claim 7 may be placed below the ground level near the earth's surface and that heat from the bottom of a geothermal well may be transferred to the thermoelectric generator by the open tube heat exchanger of claim 2 that may extend to the bottom of a geothermal well and may absorb a high-level of thermal energy; and,
it is claimed that the high-pressure, high-energy cryogenic vapor that has absorbed substantial thermal energy at the bottom of the geothermal well passes between the outside of the thermoelectric generator and the well casing as it rises to the surface; and,
it is claimed that the high-pressure, high-energy cryogenic vapor may air-lift pump hot water from the well that also flows between the outside of the thermoelectric generator and the casing of the well as it rises to the surface; and,
it is claimed that the hot cryogenic vapor and the hot water transfer heat to the thermoelectric generator that may be converted to electricity thermoelectrically.

13. It is claimed that the thermoelectric generator of claim 7 may be placed above ground level and that heat from the bottom of a geothermal well may be transferred to the thermoelectric generator by the open tube heat exchanger of claim 2 that may extend to the bottom of a geothermal well and may absorb a high-level of thermal energy; and,
it is claimed that the high-pressure, high-energy cryogenic vapor may air-lift pump hot water from the well that flows to the surface; and,
it is claimed that the cryogenic vapor may transfer heat that may be converted to electricity thermoelectrically to the thermoelectric generator at the surface; and,
it is claimed that the hot water may transfer heat that may be converted to electricity thermoelectrically to the thermoelectric generator at the surface.

14. An injection well is hereby claimed.

15. It is claimed that water air-lift pumped to the surface may be injected into the earth via an injection well after heat has been extracted from the water.

16. It is claimed that water air-lift pumped to the surface may be electrolyzed into hydrogen and oxygen; and,
it is claimed that electricity generated may be used to electrolyze water into hydrogen and oxygen.

17. A solid-oxide electrolyzer is hereby claimed.
It is claimed that a solid-oxide electrolyzer may be used to electrolyze high-temperature steam produced from heated water air-lift pumped to the surface into hydrogen and oxygen.

18. A catalyst is hereby claimed.
It is hereby claimed that a catalyst such as iron filings or nickel and aluminum, etc. may enhance the electrolysis process of claim 17 to electrolyze water into hydrogen and oxygen.

19. It is hereby claimed that a portion of the hydrogen produced in claim 17 is combusted to produce a high-level of heat to transform water into steam and to maintain the operating temperature needed by the solid-oxide electrolyzer of claim 17.

20. it is claimed that substantial geothermal heat may be found deep within the earth at almost any location in the world; and,
it is claimed that substantial pressure is found within the earth at great depths; and,
it is claimed that cryogen forced into the U-tube heat exchanger of claim 1 or the open tube heat exchanger of claim 2 that passes through the geothermal thermoelectric generator of claim 7 and the U-tube heat exchanger or open tube heat exchanger may extend to the bottom of a geothermal well of claim 7; and,
it is claimed that the cryogen must be forced into the U-tube heat exchanger or open tube heat exchanger at a greater pressure than the pressure at the bottom of the geothermal well.

21. It is claimed that the high-pressure cryogen forced into the U-tube heat exchanger of claim 1 or the open tube heat exchanger of claim 2 will be vaporized due to the temperature within the geothermal heat source; and,
it is claimed that the cryogen will attempt to expand on the order of a thousand times in volume as a result of vaporization and of continued heating; and,
it is claimed that the cryogenic vapor will gain a substantial increase in pressure as a result of not being allowed to expand; and,
it is claimed that the cryogenic vapor will gain thermal energy within the geothermal well from the thermal energy (heat) within the earth; and,
it is claimed that due to the high-pressure in which cryogen is forced into the geothermal well that the cryogenic vapor will become energetic, extremely high-pressure air due to the heat received within the geothermal well.

22. It is claimed that energetic, extremely high-pressure, high-enthalpy cryogenic vapor that rises from the geothermal well has the capability to operate a rotary vane motor of claim 4, bladeless turbine, or heat turbine capable of driving an electric generator of claim 4 and is capable of performing other forms of mechanical drive or pneumatic work due to its great kinetic energy.
